(19) United States
(12) Patent Application Publication
(10) Pub. No.: US 2023/0042041 A1
(43) Pub. Date: Feb. 9, 2023

(54) HOUSING, OPTOELECTRONIC SEMICONDUCTOR COMPONENT AND PRODUCTION METHOD

(71) Applicant: OSRAM Opto Semiconductors GmbH, Regensburg (DE)

(72) Inventors: Karlheinz ARNDT, Bad Abbach (DE); Matthias GOLDBACH, Pentling (DE); Simon JEREBIC, Donaustauf (DE); Matthias HOFMANN, Regensburg (DE); Markus BOSS, Regensburg (DE); Constantin HETZER, Abensberg (DE); Harald JAEGER, Regensburg (DE); Jens EBERHARD, Lemgo (DE); Sebastian STOLL, Coburg (DE)

(21) Appl. No.: 17/792,679

(22) PCT Filed: Dec. 18, 2020
(86) PCT No.: PCT/EP2020/087189

§ 371 Date: Jul. 13, 2022

(30) Foreign Application Priority Data
Jan. 13, 2020 (DE) 10 2020 100 542.3
Mar. 9, 2020 (DE) 10 2020 106 250.8

(51) Int. Cl. H01L 33/48; H01L 33/62; H01L 33/10; H01L 33/00; H01L 33/56

(52) U.S. Cl. CPC H01L 33/486; H01L 33/62; H01L 33/10; H01L 33/005; H01L 33/56; H01L 2933/0066; H01L 2933/005

(57) ABSTRACT

The Invention relates to a housing for an optoelectronic semiconductor component, comprising: a housing main body, which has a chip mounting side, at least two electrical conducting structures in and/or on the housing main body, and a plurality of drainage structures on the chip mounting side. The electrical conducting structures form, on the chip mounting side, electrical contact surfaces for at least one optoelectronic semiconductor chip and the drainage structure are designed as means for feeding a liquid potting material to the electrical contact surfaces.

A housing for an optoelectronic semiconductor component, an optoelectronic semiconductor component and a production method for optoelectronic semiconductor components are provided.

One object to be achieved is to provide an optoelectronic semiconductor component which has a high efficiency.

This object is achieved inter alia by a housing, by an optoelectronic semiconductor component and by a production method for optoelectronic semiconductor components, having the features of the independent patent claims. The dependent claims relate to preferred refinements.

In at least one embodiment, the housing, which is preferably intended for an optoelectronic semiconductor component, comprises:
a housing base body, which has a chip mounting side,
at least two conductor structures, such as electrical lines or lead frame parts, in and/or on the housing base body, and
a plurality of drainage structures on the chip mounting side,
   wherein
the conductor structures on the chip mounting side form electrical contact pads for at least one optoelectronic semiconductor chip, and
the drainage structures are configured as feeds for a preferably liquid encapsulation material to the electrical contact pads.

An optoelectronic semiconductor component is furthermore provided, which preferably comprises a housing as described in connection with one or more of the embodiments mentioned above. Features of the optoelectronic semiconductor component are therefore also disclosed for the housing, and vice versa.

In at least one embodiment, the optoelectronic semiconductor component comprises
a housing,
at least one optoelectronic semiconductor chip on the electrical contact pads, and
a reflective encapsulation, which is produced from the liquid encapsulation material, wherein
the encapsulation reaches under the at least one optoelectronic semiconductor chip and leaves side faces of the at least one semiconductor chip predominantly or entirely free.

A method for producing an optoelectronic semiconductor component as described in connection with one or more of the embodiments mentioned above is furthermore provided. Features of the optoelectronic semiconductor component are therefore also disclosed for the method, and vice versa.

In at least one embodiment, the method is used to produce one or more optoelectronic semiconductor components according to at least one of the embodiments above and preferably comprises the following steps, particularly in the order specified:

A) producing the housing,
B) mounting the at least one optoelectronic semiconductor chip on the electrical contact pads, and
C) producing the encapsulation,
wherein
an encapsulation material, on which the encapsulation is produced, is applied in the liquid state in one or more land zones,
the land zone or land zones lie next to the optoelectronic semiconductor chip as seen in a plan view,
the drainage structures extend through the land zone or land zones or begin in the land zone or land zones, and
the encapsulation material passes from the land zone or land zones through the drainage structures to the optoelectronic semiconductor chip, in particular by capillary action.

A mold, with which housings as provided in connection with one or more of the embodiments mentioned above may be produced, is furthermore provided. Features of the housing and of the method are therefore also disclosed for the mold, and vice versa.

The housing as described here is based, in particular, on the technical problem that the third generation of 4014 LEDs, i.e. light-emitting diodes, of the SYNIOS E4014 family from the manufacturer Osram Opto Semiconductors GmbH is intended to be 10% more efficient than the second generation.

Besides the brightness increase by using brighter LED chips, the absorption losses in the LED package are also intended to be reduced accordingly. By many measurements and optical simulations, to this end the loss chain for the light generated has been determined. For example, it has been established that a white TiO₂ encapsulation reflects better than a white epoxy molding compound, abbreviated to EMC.

ESD protection diodes also absorb light when they are not concealed under a thick layer of TiO₂ encapsulation. ESD stands for ElectroStatic Discharge. It has also been found that gold wires absorb light. Metal faces, even when coated with silver, absorb light and should therefore likewise be covered thickly with a TiO₂ encapsulation. It has furthermore been found that large plane surfaces can scarcely be covered with a uniformly thick TiO₂ encapsulation layer because the TiO₂ carrier silicone runs up at the chip edges and housing edges and forms only a small layer thickness on free faces.

It has furthermore been found that reflector walls which are located close to the LED chip absorb more light and also age faster than reflector walls which are located further away from the chip. It has furthermore been established that shallow reflector walls reflect better than steep walls. It is correspondingly feasible that an LED chip which is seated centrally in a symmetrical cavity of fixed predetermined size emits more light from the component than would be the case with an asymmetrically placed chip.

Although the lower sides, in particular of sapphire LED chips, are mirrored, this is not often not the case as far as the outermost edge. If a sapphire LED chip is seated on a metal pad, then a lead frame made of metal, also referred to as LDF metal, absorbs a part of the light which emerges from the chip at these edges. The chip lower side is therefore advantageously wetted with TiO₂ silicone at the locations which are not mirrored. The side faces of sapphire chips, on the other hand, should as far as possible not be wetted with TiO₂ encapsulation because this would generate disadvantageous reflections back into the LED chip. A solder with which a semiconductor chip is fastened is preferably surrounded, particularly in direct contact, all around by the reflective encapsulation in the lateral direction.

Here, an LED design that makes it possible to wet the chip edges of the lower side fully, in particular with a TiO₂ silicone encapsulation, while leaving the side faces of the chip free, is described.

The comments below preferably relate to a sapphire LED flip-chip which is sufficiently ESD-stable and requires neither an ESD protection diode nor connecting wires, but is soldered on. In contrast thereto, other LED chips may however also be used.

As an alternative to the concept as described here, flip-chips are placed on a closed frame made of epoxy molding compound, abbreviated to EMC. The applied TiO₂ silicone does not then go under the chip, but remains on the frame. This notably entails the following disadvantages:
The solder is confined, and a flux cannot evaporate freely.
A solder paste may be quenched and solder balls may be formed.
The EMC is not as reflective as the TiO₂ silicone.
Optical simulations show that it is optically advantageous for the solder to be confined in a light-tight fashion. This is not achieved with an EMC frame.
Flux residues under the LED chip cannot be cleaned well because of the frame.

The design as described here for the housing and for the semiconductor component achieves positive effects in particular by the following technical features, these technical features being implementable individually, in any combination or as a whole:
There are defined TiO₂ jetting land zones. Regions facing away from the chip in a housing cavity are highly rounded so that TiO₂ encapsulation material cannot accumulate there.
Drainage structures conduct the dispensed TiO₂ encapsulation material, which preferably contains at least one silicone, from the jetting land zones directly to the chip. Drainage structures are, for example, in principle approximately 90° inner edges which lead from the land zones directly to the chip, preferably by using capillary action.
The inner longitudinal edges of the housing may also be used as drainage paths. Thus, TiO₂ encapsulation material also reaches optionally present small drainage structures on the longitudinal edges of the chip. This is a special case since models such as the LEDs of the E4014 family are usually narrow.
The chip should be seated on the drainage structures so that they may simultaneously be used as a stand-off during the chip soldering.
The drainage structures extent partially or entirely radially with respect to the chip.
The drainage structures are as narrow as is technically possible.
The drainage structures are as sharp-edged as is technically possible on the longitudinal side, in order to achieve a high capillary action.
The drainage structures are all equally high at the ends on which the chip is seated. In this way, wobbling or tilting of the chip may be prevented.
There are preferably at least three drainage structures, so that the chip is seated stably and cannot tilt.

The technical features mentioned above offer for example the following advantages, individually or in combination:
The TiO₂ encapsulation is caused by using capillary action to flow for the most part to where the encapsulation material should be, namely under the chip.
Regions facing away from the chip in the cavity of the housing are highly rounded so long as edges are not intended as a drainage path.
The drainage structures simultaneously form a stand-off for the chip soldering. Heights of from 60 μm to 80 μm inclusive are preferred. The final solder thickness is therefore rigidly set and is independent of the amount of solder over wide ranges.
The open radial arrangement of the drainage structures has the positive effect that solder paste whose width is squeezed remains connected to the main mass of solder under the chip and may be drawn back below the chip during the melting. In this regard, it should be noted that solder paste typically experiences a volume shrinkage of about 50% during melting, because flux with a low density for the most part evaporates and only metals such as SnAgCu remain in the solidified solder connection, even though typically only less than 20% flux by weight is contained in the solder paste.
The open radial arrangement of the drainage structures allows easy evaporation of the flux. Less flux residues therefore remain overall in the cavity.
The open radial arrangement of the drainage structures leads to better cleaning outcomes of flux remainders, because the cleaning liquid reaches the solder location more easily during the washing.

The aforementioned technical features of the housing as described here are therefore used in particular to underpin the chip as much as possible with TiO₂ encapsulation, in order to maximize the optical efficiency. Optical simulations show that the solder should be restricted as far as possible thickly and all around in an optically leaktight fashion.

It is desirable to make the TiO₂ encapsulation underfill process possible with a range of materials, especially silicones, that is as wide as possible. In alternative TiO₂ underfill designs, the processing outcome is strongly dependent on the silicone used and its viscosity. The design as described here with drainage paths and the avoidance of undesired silicone accumulations can make the TiO₂ underfill process more tolerant in relation to certain material properties, such as viscosity and/or wetting angle.

According to at least one embodiment, two or more than two of the conductor structure are configured as electrical conductor structures. For example, these electrical conductor structures are adapted to electrically contact the at least one optoelectronic semiconductor chip. In the finished semiconductor component, the electrical conductor structures are used as electrical contacts outward.

According to at least one embodiment, one or more of the conductor structures are configured as thermal conductor structures. This means that the thermal conductor structures are adapted for heat dissipation of the at least one optoelectronic semiconductor chip. To this end, the at least one thermal conductor structure is electrically insulated from the electrical conductor structures. In particular, the at least one thermal conductor structure is potential-free.

When only conductor structures are mentioned below, the relevant comments preferably refer both to the at least one thermal conductor structure and to the electrical conductor structures.

According to at least one embodiment, the conductor structures, that is to say preferably both the at least one thermal conductor structure and the electrical conductor structures, are respectively formed by metal lead frame parts. For example, the conductor structures are produced from a metal sheet by means of stamping. As an alternative to metal lead frame parts, the conductor structures may also be produced by coatings, in particular metal coatings, on a carrier such as a ceramic. In this case, the conductor structures are for example electrolytically applied coatings for electrical connection faces and/or conductor tracks.

According to at least one embodiment, the lead frame parts are mechanically connected to one another by the housing base body.

This means that without the housing base body there would be no firm mechanical connection between the lead frame parts.

According to at least one embodiment, the drainage structures are respectively formed in part by an edge. The edge is, in particular, formed by mutually abutting faces of the housing body. An angle of these faces at the edge is preferably at least 60° or 75° and/or at most 110° or 95°. In particular, there is a right angle or approximately a right angle between the relevant faces at the edge.

The drainage structures are in this case therefore faces abutting one another approximately at a right angle. The drainage structures therefore act in particular because of capillary forces at the edge. Furthermore, the liquid encapsulation material may be guided along the edge.

Such drainage structures formed by a sharp edge are preferably defined by an elevation, in particular by a strip, which rises above the chip mounting side. This strip is preferably configured integrally with the housing base body. Such strips have, as seen in a cross section, for example a rectangular, trapezoidal or semicircular cross section or combinations thereof. In particular, the strips as seen in a cross section are formed by a rectangle which is followed in the direction away from the chip mounting side by an arched structure. In other words, the strips may respectively define a preferably associated pair of the drainage structures.

According to at least one embodiment, the drainage structures respectively comprise or consist of two strips or more than two strips, the strips rising above other parts of the chip mounting side. The strips are preferably configured integrally with the housing base body.

If there are a plurality of strips per drainage structure, the strips may extend parallel to one another or approximately parallel to one another inside the relevant drainage structure. The strips for the relevant drainage structure may define a channel which is rectangular or trapezoidal in cross section. The strips of the relevant drainage structure may be connected to one another with a U-shape at the electrical contact pads, as seen in a plan view of the chip mounting side.

According to at least one embodiment, the housing base body comprises a cavity which forms a reflector trough. The reflector trough is preferably formed all around by side walls of the housing base body. This means that the side walls may enclose the chip mounting side all around. The chip mounting side is for example a bottom face of the cavity, in particular a planar region of the bottom face, which terminates flush with the conductor structures and/or joins flatly all around on to the conductor structures.

According to at least one embodiment, the drainage structures, in particular the strips, have a lower height than the reflector trough and therefore than the side walls. Preferably, the side walls and therefore the reflector trough are higher than the drainage structures and than the strips at least by a factor of 10 or 20 or 50.

According to at least one embodiment, the drainage structures, in particular the strips, are configured as bearing faces for the at least one optoelectronic semiconductor chip. This means that the optoelectronic semiconductor chip bears on the drainage structures, especially on the strips, in the intended arrangement.

It is possible for the drainage structures, especially the strips, to have a constant height which remains the same over the chip mounting side. As an alternative, the drainage structures may have a varying height, and may have a different height, for example a smaller or greater height, particularly in regions which are intended as bearing faces for the at least one semiconductor chip.

According to at least one embodiment, there are in total at least three or four or six and/or at most 24 or 12 or eight of the strips. This means that the housing comprises only a relatively small number of the strips, and correspondingly of the drainage structures.

According to at least one embodiment, the strips and/or the drainage structures end close to the electrical contact pads.

For example, a distance between the electrical contact pads and the associated drainage structures and/or strips is at least 5 μm for 10 μm or 30 μm and/or at most 0.1 mm or 50 μm. A space-saving arrangement may be achieved in this way, the semiconductor chip being placeable securely in the housing.

As an alternative, the drainage structures and/or strips may end flush with the electrical contact pads.

According to at least one embodiment, at least one of the drainage structures and/or of the strips ends in a region between the electrical contact pads. This applies in particular for the shorter drainage structures which may extend from the longer side walls. Such drainage structures and/or strips, which reach between the electrical contact pads, may furthermore reach further than the longer drainage structures and/or strips under the optoelectronic semiconductor chip to be mounted.

According to at least one embodiment, the drainage structures and/or the strips are separate structures, which are not associated with one another. In particular, the drainage structures and/or the strips do not form a surrounding edge or frame around the at least one semiconductor chip. This means that all the drainage structures and/or strips may extend radially as far as the electrical contact pads or as far as a region between the electrical contact pads.

According to at least one embodiment, the side walls of the housing base body merge continuously into the chip mounting side locally or along the entire circumference of the chip mounting side. The side walls and the chip mounting side may form a rounding with a radius of curvature of at least 1 mm, in particular at least 2 mm or at least 3 mm, as seen in a cross section perpendicular to the electrical contact pads.

As an alternative, it is possible for the side walls of the housing base body to merge with a sharp edge into the chip mounting side locally or along the entire circumference of the chip mounting side. Such a sharp edge may form one of the drainage structures. In particular, there is such a sharp transition between the side walls and the chip mounting side along longitudinal sides of the reflector trough.

According to at least one embodiment, the housing is rectangular or approximately rectangular, that is to say rectangular with rounded corners, as seen in a plan view of chip mounting side.

According to at least one embodiment, the electrical contact pads are arranged symmetrically along a longitudinal axis of the housing base body as seen in a plan view. As an alternative thereto, the contact pads may also be arranged asymmetrically.

According to at least one embodiment, at least two, in particular precisely two, of the drainage structures extend along the longitudinal axis, and at least two further, in particular precisely two further, preferably shorter drainage structures are oriented transversely with respect to the longitudinal axis. This means that the drainage structures may have a cross-shaped geometry as seen in a plan view, there preferably being no drainage structures in the middle of the relevant cross. The relevant cross may comprise, as seen in a plan view, bars which are formed by the drainage structures and extend at a right angle.

According to at least one embodiment, the for example shorter drainage structures, which are oriented transversely with respect to the longitudinal axis, are adapted to guide the liquid encapsulation material from the longer side walls of the cavity to an intermediate space between the electrical contact pads. To this end, the drainage structures preferably conduct a flow of the liquid encapsulation material, which extends along the side walls, to the contact pads.

According to at least one embodiment, at least one of the drainage structures or all the drainage structures, which extend along the longitudinal axis of the housing base body, end at a distance from the side walls. This means that there is a gap, in which a thickness of the housing base body may be less than in the region of the relevant drainage structure, between the relevant drainage structure and the assigned side wall. It is possible for the at least one relevant drainage structure to end while still on the in particular plane chip mounting side and therefore not reach as far as an optional, for example rounded, cavity end.

According to at least one embodiment, at least one of the drainage structures or all the drainage structures, which extend along the longitudinal axis of the housing base body, end on or in the assigned side wall. This means that at least one relevant drainage structure may merge without a gap, in particular merge continuously, along the longitudinal axis into the assigned side wall.

The drainage structures which are oriented transversely with respect to the longitudinal axis preferably end in or on the respectively assigned side wall.

According to at least one embodiment of the semiconductor component, the encapsulation is made of a reflective material. The encapsulation preferably appears white to an observer. The reflectivity of the encapsulation in the visible spectral range is preferably at least 80% or 90% or 95%.

According to at least one embodiment, the at least one optoelectronic semiconductor chip is a light-emitting diode, abbreviated to LED, or a laser diode, abbreviated to LD. Different types of semiconductor chips, for example for the emission of different colors, may be installed in the semiconductor component.

According to at least one embodiment, the semiconductor chip bears or all the semiconductor chips bear on all or respectively on at least three or on at least four of the drainage structures.

According to at least one embodiment, the strips which define the drainage structures have a height of at least 10 μm or 30 μm or 60 μm and/or at most 200 μm or 100 μm or 80 μm. In particular, a height of the relevant strips is between 30 μm and 100 μm inclusive, in relation to the chip mounting side.

According to at least one embodiment, a lower side, facing toward the chip mounting side, of the at least one optoelectronic semiconductor chip is covered entirely or by far predominantly by the reflective encapsulation together with a connecting means and together with the drainage structures. By far predominantly means, for example, to at least 95% or 98% or 99% or 99.8%. The connecting means is in this case preferably a solder or comprises a solder. As an alternative, the connecting means may also be an electrically conductive adhesive.

According to at least one embodiment, the connecting means is bounded all around entirely or predominantly laterally by the encapsulation in a direction parallel to the chip mounting side. The connecting means is preferably covered directly by the encapsulation.

According to at least one embodiment, the encapsulation is made of a matrix material, in particular a silicone, and of reflective particles, in particular consisting of or comprising a metal oxide such as TiO₂. The encapsulation is therefore preferably white and highly reflective.

According to at least one embodiment, the housing base body is made of an epoxide material, preferably of a white epoxide material. Relative to the encapsulation, the material of the housing base body has a lower reflectivity. It is possible for the material of the housing base body not to be entirely opaque, but to be translucent. As an alternative, the housing base body may also be made of an unsaturated polyester, such as UP resin.

According to at least one embodiment, the at least one optoelectronic semiconductor chip is a sapphire flip-chip or the semiconductor chips are such chips.

According to at least one embodiment, all the electrical connection faces of the semiconductor chip are assigned uniquely to the electrical contact pads of the housing. As an alternative, a plurality of connection faces may be applied on a common contact pad.

According to at least one embodiment, a sapphire substrate of the semiconductor chip faces away from the chip mounting side. This means that the chip mounting side faces toward a semiconductor layer sequence of the at least one semiconductor chip.

According to at least one embodiment, the at least one optoelectronic semiconductor chip comprises a mirror on a lower side facing toward the chip mounting side. The mirror may be a metal mirror or a dielectric mirror or a mixture of both.

According to at least one embodiment, the mirror ends at a distance from an edge of the lower side of the relevant semiconductor chip. A region, not covered by the mirror, of the lower side is preferably covered entirely or predominantly by the encapsulation. In this way, a high reflectivity is ensured because of the encapsulation, even in regions of the lower side in which there is no mirror.

According to at least one embodiment, the semiconductor module furthermore comprises a filling which covers the at least one optoelectronic semiconductor chip and touches the encapsulation. As seen in a plan view of the chip mounting side, the filling preferably encloses the semiconductor chip all around. The at least one semiconductor chip is preferably covered entirely by the filling, likewise the encapsulation.

According to at least one embodiment, the filling contains one or more phosphors, so that the semiconductor chip generates in particular blue light, and the semiconductor component may be configured overall for the emission of white light.

According to at least one embodiment, the semiconductor component is free of a protection diode against damage by electrostatic discharges and/or the semiconductor component is free of bonding wires. This means that the at least one optoelectronic semiconductor chip may be the only chip in the reflector trough, so that only optoelectronic semiconductor chips may be present.

According to at least one embodiment, the encapsulation material from which the encapsulation is produced is applied in the liquid state in land zones. The land zones lie next to the optoelectronic semiconductor chip as seen in a plan view.

According to at least one embodiment, the land zones cover the drainage structures. The land zones in this case lie partially, preferably predominantly, next to the drainage structures. The drainage structures extend through the land zones and/or begin in the land zones. As an alternative, it is possible for the land zones to lie entirely next to the drainage structures, particularly in a gap between the drainage structures and the side walls, especially as seen along the longitudinal axis of the housing. This means that the land zones may be located in a region in which the associated at least one drainage structure is interrupted.

According to at least one embodiment, the encapsulation material is guided from the land zones through the drainage structures to the optoelectronic semiconductor chip, in particular by means of capillary action. The encapsulation material therefore extends in particular along edges which are formed by the strips which define the drainage structures.

According to at least one embodiment, the housing is produced by means of casting, injection molding and/or pressing. In this case, the mold may preferably be used. The mold forms the negative for the chip mounting side, the reflector trough and the drainage structures.

According to at least one embodiment, the encapsulation material is applied exclusively in the region of the land zones in step C) by means of jetting. In this case, unintended splashes of the encapsulation material, which land outside the land zones in the housing, remain neglected. A distance of the land zones from the at least one optoelectronic semiconductor chip is preferably at least 0.3 mm or 0.4 mm and/or at most 1 mm or 0.7 mm, in order to achieve a space-saving arrangement and to prevent contamination on the optoelectronic semiconductor chip by the encapsulation material.

A housing as described here, an optoelectronic semiconductor component as described here, a mold as described here, and a method as described here will be explained in more detail with reference to the drawing with the aid of exemplary embodiments. References which are the same in this case indicate elements which are the same in the individual figures. Unless otherwise stated, however, true-to-scale relationships are not represented in this case, but instead individual elements may be represented exaggeratedly large for better understanding.

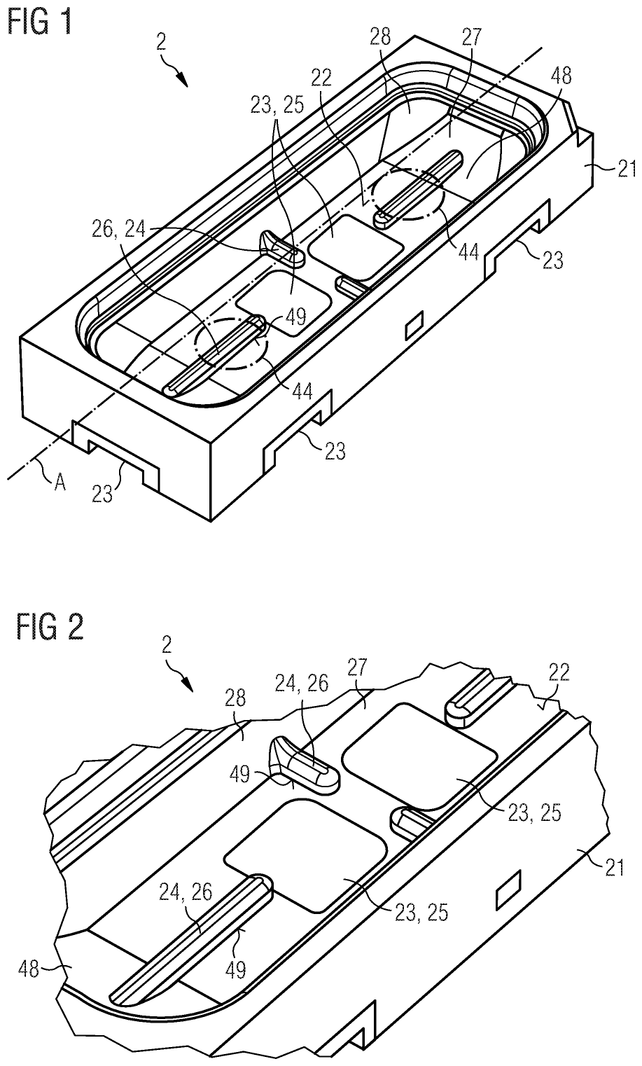

FIG. 1 shows a schematic perspective representation of an exemplary embodiment of a housing as described here,

FIG. 2 shows a detail view of the housing of FIG. 1,

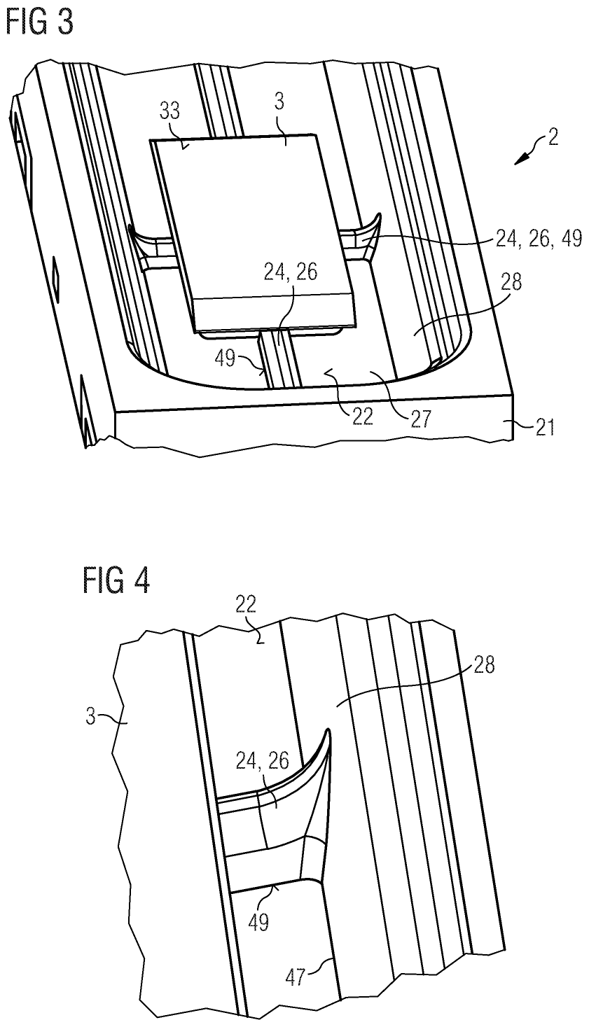

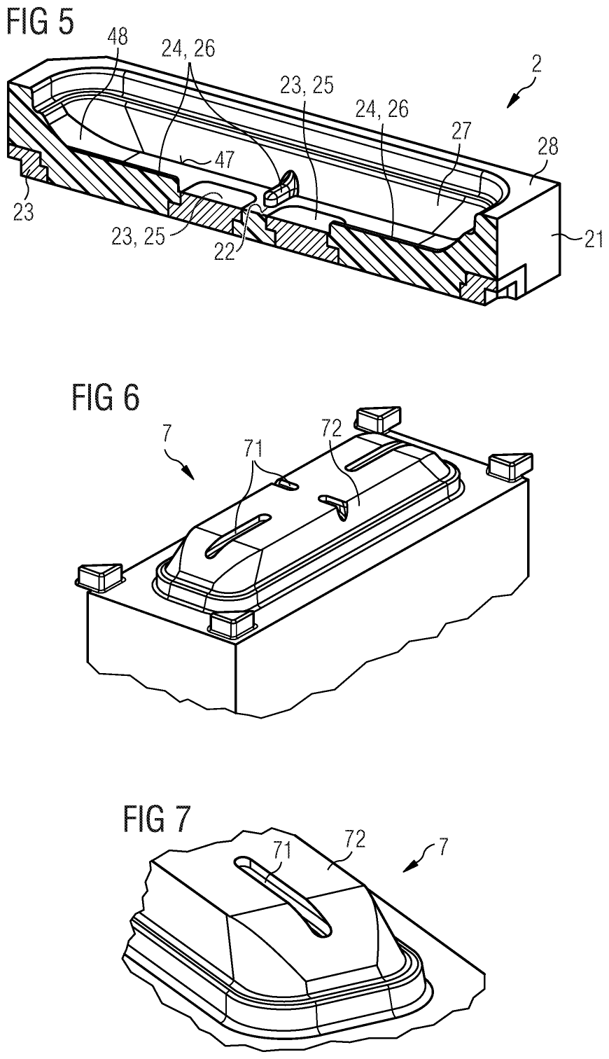

FIGS. 3 and 4 show further detail views of the housing of FIG. 1 with a mounted semiconductor chip,

FIG. 5 shows a schematic sectional representation of the housing of FIG. 1,

FIG. 6 shows a schematic perspective representation of a mold for producing exemplary embodiments of housings as described here,

FIG. 7 shows a detail view of FIG. 6,

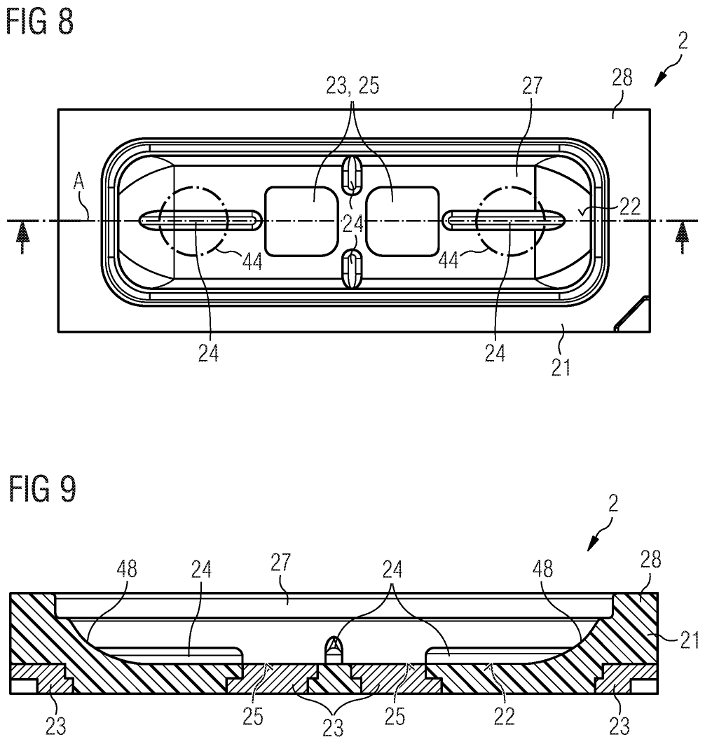

FIG. 8 shows a schematic plan view of an exemplary embodiment of a housing as described here,

FIG. 9 shows a schematic sectional representation of the housing of FIG. 8,

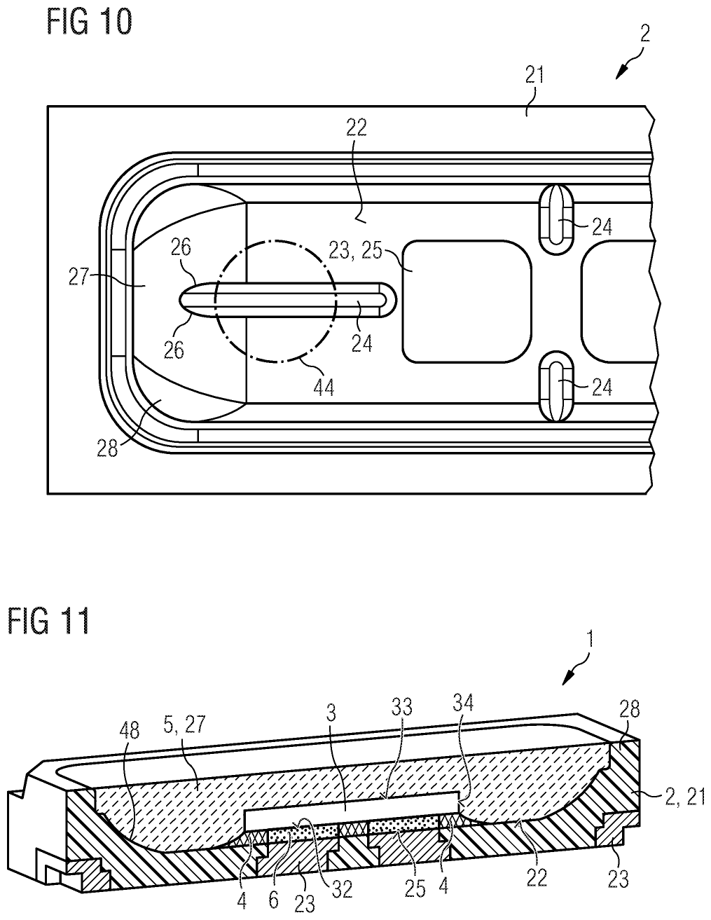

FIG. 10 shows a schematic detail view of the representation of FIG. 8,

FIG. 11 shows a schematic perspective sectional representation of an exemplary embodiment of an optoelectronic semiconductor component as described here,

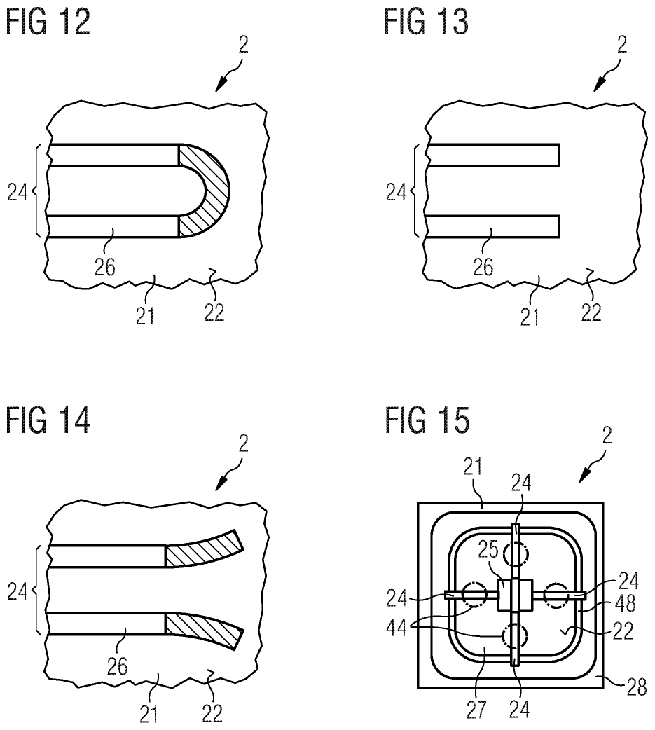

FIGS. 12 to 15 shows a schematic plan views of exemplary embodiments of housings as described here,

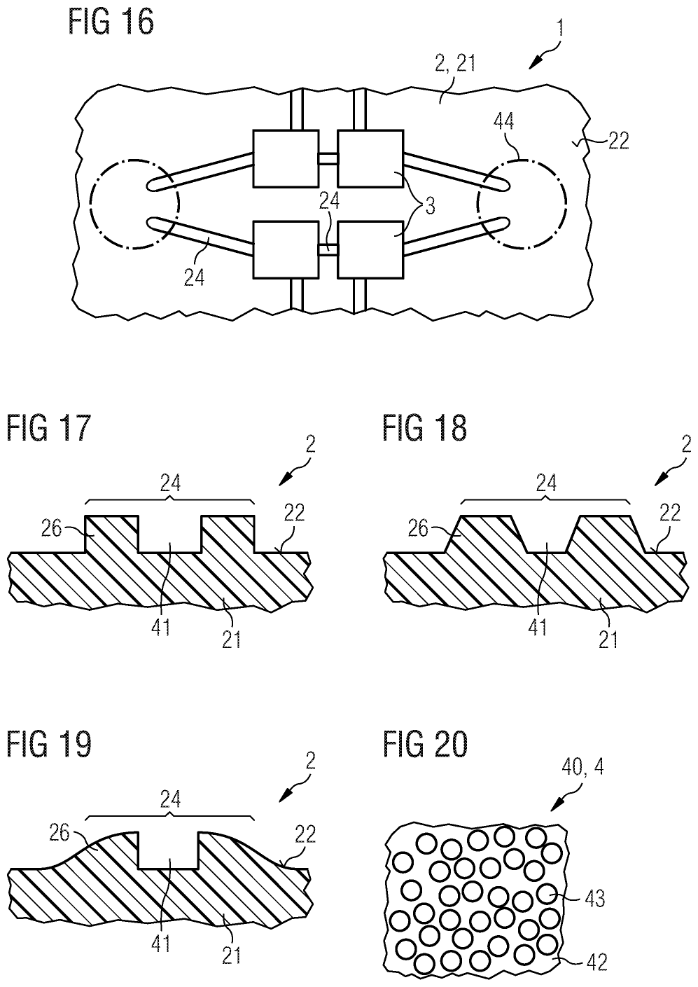

FIG. 16 shows a schematic plan view of an exemplary embodiment of an optoelectronic semiconductor component as described here,

FIGS. 17 to 19 show schematic sectional representations of exemplary embodiments of housings as described here,

FIG. 20 shows a schematic representation of a reflective encapsulation and of an encapsulation material for optoelectronic semiconductor components as described here,

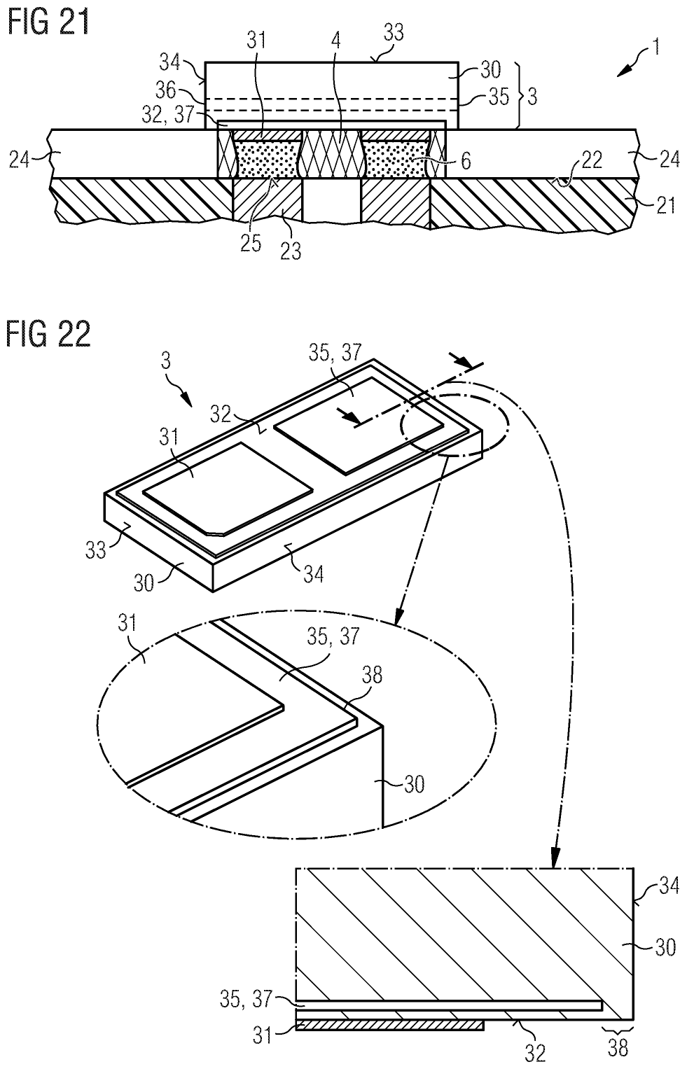

FIGS. 21 and 23 show schematic sectional representations of exemplary embodiments of the optoelectronic semiconductor components as described here,

FIG. 22 shows a schematic representation of an exemplary embodiment of an optoelectronic semiconductor chip for optoelectronic semiconductor components as described here,

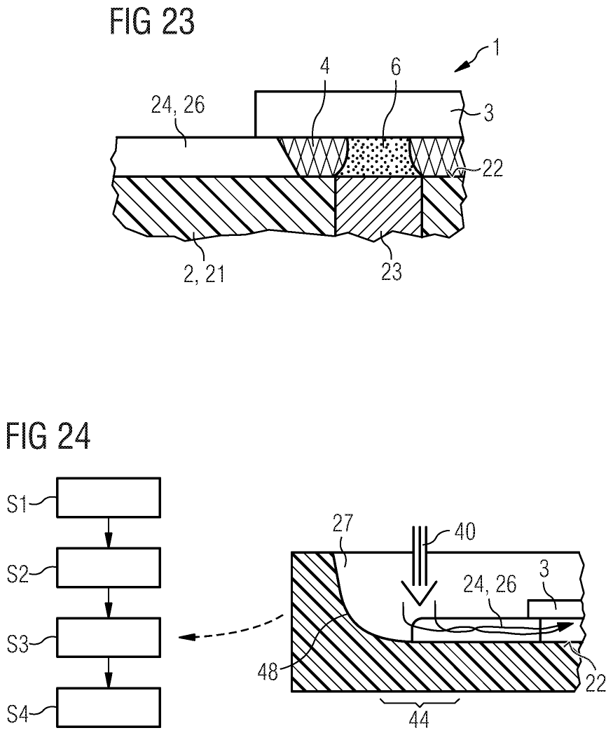

FIG. 24 shows a block diagram of an exemplary embodiment of a method as described here for producing optoelectronic semiconductor components,

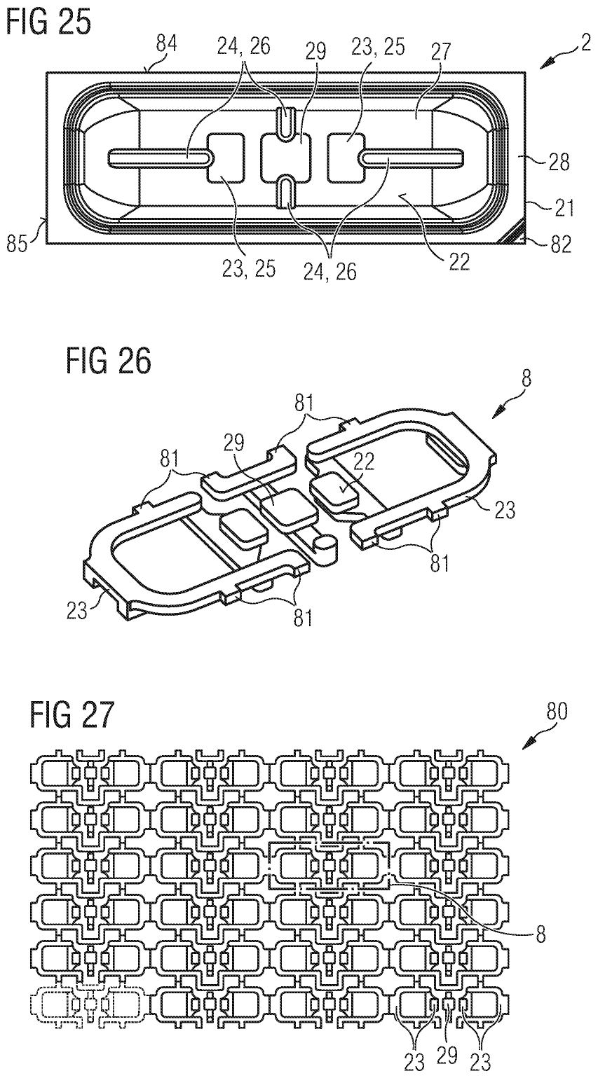

FIG. 25 shows a schematic plan view of an exemplary embodiment of a housing as described here,

FIG. 26 shows a schematic perspective representation of a lead frame for the housing of FIG. 25,

FIG. 27 shows a schematic plan view of a lead frame panel for the lead frame of FIG. 25,

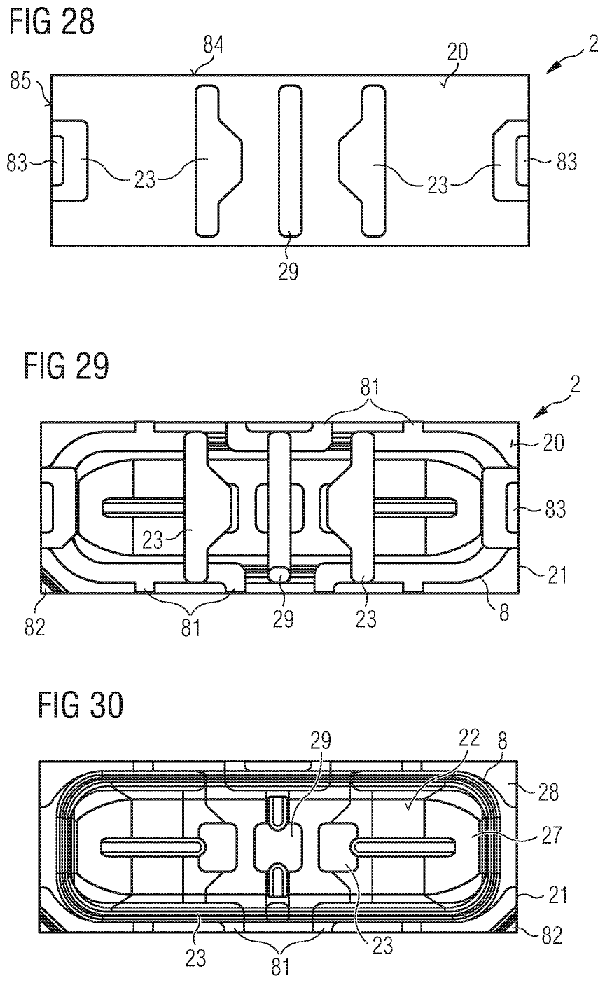

FIGS. 28 to 32 show various schematic side views of the housing of FIG. 25,

FIG. 33 shows a schematic plan view of a partially injection-molded lead frame panel for the housing of FIG. 25, and

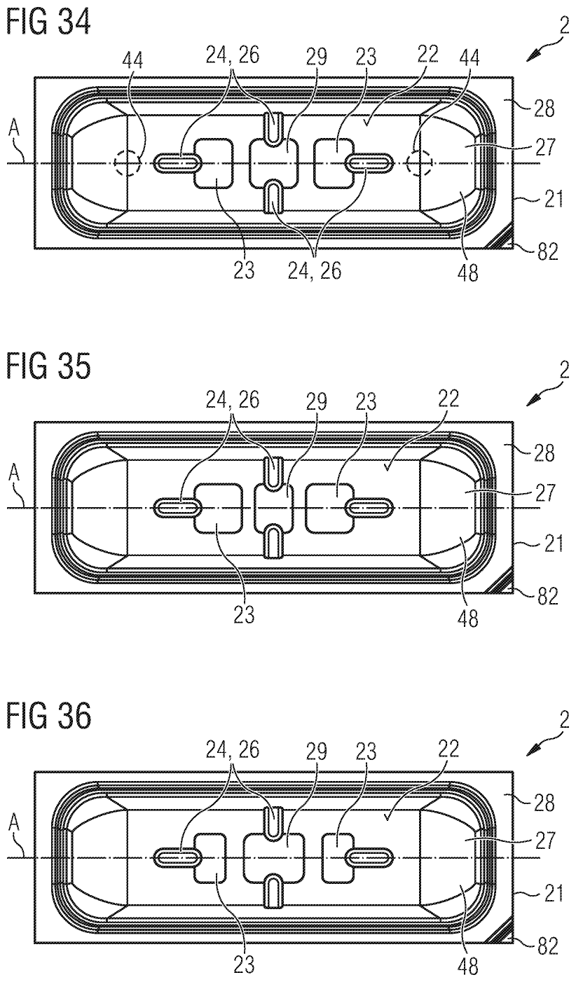

FIGS. 34 to 36 show schematic plan views of further exemplary embodiments of housings as described here.

FIGS. 1 to 5 illustrate an exemplary embodiment of a housing 2. The housing 2 comprises a housing base body 21 with a cavity 27. The cavity 27 is delimited by surrounding side walls 28, which merge at a rounded cavity end 48 into an approximately plane chip mounting side 22.

Two electrical conductor structures 23, which are formed by lead frame parts, are integrated in the housing base body 21. Instead of lead frame parts, it is also possible for electrical conductor tracks to be applied onto the housing base body 21, as may also be the case in all other exemplary embodiments. Electrical contact pads 25 are formed by the electrical conductor structures 23.

Through land zones 44 for an encapsulation material (not shown), a plurality of drainage structures 24 which are defined by strips 26 extend substantially along a longitudinal axis A. The strips 26 rise above the chip mounting side 22 and are integrally connected to the housing base body 21. The drainage structures 24 and the strips 26 extend radially in relation to a position of a semiconductor chip 3 (only shown in FIGS. 3 and 4) to be fitted in the housing 2.

Edges 49 are defined by the strips 26 and the chip mounting side 22. There is approximately a right angle at the edges 49. When an encapsulation material (not shown) for the encapsulation 4 subsequently to be formed in the housing 2 is applied in the land zones 44, this encapsulation material is guided along the edges 49 to the electrical contact pads 25 and the semiconductor 3.

As seen in a plan view, the strips 26 for the drainage structures 24 extend for example in the shape of a cross, a central region of the cross being free of the drainage structures 24. The drainage structures 24 serve as mounts for the semiconductor chip 3.

As seen in a cross section, the strips 26 comprise a rectangular base followed by an approximately semicircular dome. Other shapes of the strips 26 are likewise possible.

At the ends of the cavity 27, there are regions 48 running out relatively shallowly. The longer strips 26 emerge from these regions 48. The shorter strips 26 emerge from the longer side walls 28 of the cavity 27. In this case, the longer side walls 28 optionally merge with a sharp edge into the chip mounting side 22 on a further edge 47. As an alternative, there may also be a rounding in this transition region toward the chip mounting side 22.

It may be seen particularly in FIG. 4 that the shorter strips 26, which emerge from the longer side walls 28, are configured to be raised at the side walls 28. The effect achieved by this is that the encapsulation material does not spill over these strips 26 but is guided to the semiconductor chip 3. It is possible for the shorter strips 26 to have a rounding toward the side walls 28 along the edge 49. The shorter strips 26 are optional.

In contrast to the representation in FIGS. 1 to 5, such a further edge 47 may be present all around the cavity 27. As an alternative, there may be a region 48 running out relatively shallowly around the cavity 27. The same applies for all other exemplary embodiments.

FIGS. 6 and 7 illustrate a mold 7 with which, in particular, the housing of FIGS. 1 to 5 may be produced. The mold 7 is in particular a casting mold or a pressing mold. The mold 7 comprises a trough 72 for the cavity 27 of the housing 2. In the trough 72, there are a plurality of channels 71 for the strips 26 of the housing 2. With such a mold 7, the drainage structures 24 may be produced efficiently. For example, the chip mounting side 22 is produced on the upper side of the trough 72 by means of grinding and the channels 71 are generated by means of milling. In the same way, correspondingly configured molds 7 may be employed for the production of all other exemplary embodiments.

FIGS. 8 to 10 illustrate a further exemplary embodiment of the housing 2. The housing 2 comprises the housing base body 21 with the cavity 27. The cavity 27 is delimited by the surrounding side walls 28, which merge at the rounded cavity end 48 into the plane or approximately plane chip mounting side 22.

The strips 26 form channels 41, which define the drainage structures 24 through which the encapsulation material (not shown) is guided from the land zones 44 to the electrical contact pads 25, in particular because of capillary forces. The land zones 44 are preferably jetting land zones, so that the encapsulation material may be applied purposely from nozzles (not shown) only in the region of the land zones.

In addition to the drainage structures 24 along the longitudinal axis A, there are optionally further, transversely extending and shorter drainage structures 24. These shorter drainage structures 24 may conduct encapsulation material that does not enter the longer drainage structures 24 and is guided along the side walls 28, to the electrical contact pads 25. The shorter drainage structures 24 are therefore not assigned their own land zones 44 for the encapsulation material.

Because of the large radius of curvature of the rounded cavity end 48, bulky accumulation of encapsulation material in the region of the cavity end 48 is prevented.

In other regards, the comments relating to FIGS. 1 to 5 apply accordingly for FIGS. 8 to 10, and correspondingly vice versa.

FIG. 11 shows an exemplary embodiment of an optoelectronic semiconductor chip 1 which preferably comprises the housing 2 of FIGS. 1 to 5 or of FIGS. 8 to 10.

An optoelectronic semiconductor chip 3 is applied on the drainage structures (not visible in FIG. 11). The semiconductor chip 3 is preferably an LED chip, for example for the generation of blue light. The semiconductor chip 3 is preferably a flip-chip. The semiconductor chip 3 is fastened on the housing 2 by means of a connecting means 6, which is in particular a solder or an adhesive.

In order to reduce absorption losses on the housing 2 and on the connecting means 6, an encapsulation 4 which has a high reflectivity is introduced between the semiconductor chip 3 and the chip mounting side 22. The encapsulation 4 is restricted to a lower side 32 of the semiconductor chip 3 and therefore leaves side faces 34 of the semiconductor chip 3 free. The encapsulation 4 reflects light in particular better than the housing base body 21; the encapsulation 4 and the housing base body 21 may be white.

The semiconductor chip 3 is furthermore preferably embedded in a filling 5, which may fill the cavity 27 and preferably contains a phosphor.

FIGS. 12 to 14 illustrate various exemplary configuration possibilities of end regions of the drainage structures 24 of FIGS. 8 to 10 in the region close to the electrical contact pads. The drainage structures 24 of FIGS. 12 to 14 may be present in all the exemplary embodiments of the housing 2, particularly in the exemplary embodiment of FIGS. 8 to 10.

According to FIG. 12, the strips 26 extend parallel to one another and are connected at their ends by a structure (denoted by hatching in FIG. 12) which is U-shaped as seen in a plan view of the chip mounting side 22. The U-shaped structure may have the same height as the strips 26 or, as an alternative may have a reduced height.

According to FIG. 13, the strips 26 end without there being a connecting structure.

FIG. 14 illustrates that the strips 26 widen in the shape of a funnel in an end region (denoted by hatching). In other regions, the strips 26 may extend parallel to one another. The end region may be restricted to a region which is covered by the semiconductor chip (not shown in FIG. 7).

In the exemplary embodiment of the housing 2 according to FIG. 15, the housing base body 21 is squarely shaped as seen in a plan view. A region for the semiconductor chip (not shown) is arranged centrally. Arranged around this region there are four of the drainage structures 24, which extend radially towards this region. Each of the drainage structures 24 is assigned its own land zone 44. The rounded cavity end 48 surrounds the cavity 27 all around as seen in a plan view. Furthermore, corners of the cavity 27, again as seen in a plan view, are preferably likewise rounded.

The drainage structures 24 which are used in the model of FIG. 15 may be configured according to FIGS. 1 to 5 or according to FIGS. 8 to 10.

In the exemplary embodiment of the semiconductor component 1 of FIG. 16, there are a plurality of semiconductor chips 3. This is also possible in all other exemplary embodiments.

It may furthermore be seen in FIG. 16 that a plurality of the drainage structures 24 may emerge from a single land zone 44. In this case, each of the semiconductor chips 3 may be assigned a long drainage structure 24 directly from the associated land zone 44 and optionally a short drainage structure 24, in particular from side walls (not shown) of the cavity. As an option, it is furthermore possible for further drainage structures 24 to extend between neighboring semiconductor chips 3.

In other regards, the housing 2 of the exemplary embodiment of FIG. 16 is preferably the same as the housings 2 of FIG. 1 to 5, 8 to 10 or 15.

FIGS. 17 to 19 show various configuration possibilities of cross sections of the drainage structures 24, such as there may be in all the exemplary embodiments, particularly in the housings 2 of FIGS. 8 to 10.

According to FIG. 17, the strips 26 and a channel 41 formed between the strips 26 are shaped rectangularly or squarely in cross section. Edges merge into one another as sharply as possible at a right angle or approximately at a right angle.

Conversely, side faces of the strips 26 extend according to FIG. 18 at an angle of less than 90° with respect to the other regions of the chip mounting side 22, in order to be able to produce the housing base body 21 more efficiently. This angle is for example at least 75° or 80° or 85° and/or at most 89° toward the channel 41. On the sides facing away from the channel 41, this angle may be less, for example at least 15° or 30° and/or at most 75° or 60° or 45° or 35°.

In FIG. 19, it is shown that the strips 26 have rounded contours outside the channel 41. The effect achievable in this way is that capillary forces remain restricted to the channel 41.

As in all other exemplary embodiments as well, typical dimensions of the drainage structures 24 are as follows:
The strips 26 have a height of at least 30 μm and/or at most 100 μm.
A width of the strips 26 is at least 10 μm or 20 μm and/or at most 200 μm or 80 μm.
An average width of the optionally provided channel 41 is at least 20 μm or 40 μm and/or at most 100 μm or 60 μm.

FIG. 20 schematically represents the encapsulation material 40 and the encapsulation 4. These are composed of a matrix material 42, in particular a silicone, and of reflective particles 43, for example made of titanium dioxide.

It is possible for the encapsulation material to have a wetting or slightly wetting effect in relation to the housing base body 21 and therefore in relation to the drainage structures 24 during the production of the encapsulation 4, so that a contact angle of the encapsulation material may for example be less than 85° or 75° and, as an alternative or in addition, is set to be more than 50° or 65°.

In the exemplary embodiment of the semiconductor component 1 of FIG. 21, the semiconductor chip 3 is an LED chip and is composed of a substrate 30, preferably made of sapphire, and of a semiconductor layer sequence 35, preferably consisting of AlInGaN, with an active zone 36. On a side facing away from the substrate 30, there is preferably a mirror 37, although it does not reach entirely as far as the side faces 34 of the semiconductor chip 3. An emission side 33 of the semiconductor chip 3 faces away from the housing 2 and is preferably formed by the substrate 30.

The semiconductor chip 3 bears locally on the drainage structures 24, so that a distance from electrical connection faces 31 on a lower side 32 of the semiconductor chip 3 to the electrical contact pads 25 is predetermined by the drainage structures 24. The lower side 32 and the side faces 34 are separated by a sharp edge. The semiconductor chip 3 is fastened on the housing 2 by means of a connecting means 6, preferably a solder.

The connecting means 6 is covered all around by the encapsulation 4. The lower side 32 is entirely covered by the connecting means 6 together with the drainage structures 24 and the encapsulation 4. At locations where there are no drainage structures 24, the encapsulation 4 therefore reaches as far as the edge of the lower side 32, but preferably leaves the side faces 34 free.

The housing 2 of FIG. 21 is preferably configured as described in connection with FIG. 1 to 5, 8 to 10, 11 or 15.

An exemplary semiconductor chip 3 is represented in more detail in FIG. 22. In this case, an internal electrical interconnection of the semiconductor chip 3 is not depicted. It may be seen in FIG. 22 in particular that the semiconductor chip 3 comprises a region 38 not covered by the mirror 37 on the lower side 32 close to the side faces 34.

This region 38 is covered entirely or at least predominantly by the encapsulation 4 in exemplary embodiments of the semiconductor component 1, so that a high reflectivity may also be achieved in this region 38 and radiation emerging from this region 38 is directed from the encapsulation 4 to a radiation exit side of the semiconductor component 1. The side faces 34 in this case remain free of the encapsulation 4.

According to FIG. 21, the strips 26 end abruptly toward the contact faces 25, in particular with an angle of 90° or approximately 90° with respect to the chip mounting side 22. Conversely, the strips 26 may according to FIG. 23 run out continuously and relatively shallowly, for example with an angle of at least 20° and/or at most 70° with respect to the chip mounting side 22. In other regards, the exemplary embodiment of FIG. 23 is the same as that of FIG. 21.

FIG. 24 illustrates an exemplary embodiment of a production method for the semiconductor components 1.

In a first step S1, the housing 2 is produced, for example by means of pressing, injection molding or transfer molding. A plurality of housings 2, which may be present in a panel, may be produced simultaneously.

The at least one semiconductor chip 3 is subsequently mounted in step S2.

The encapsulation 4 is thereupon produced. To this end, the encapsulation material 40 is applied into the land zones 44, in particular by means of jetting or injection molding or, for example, by means of at least one nozzle (not shown). Because of capillary forces, the encapsulation material 40 is guided through the drainage structures 24 to the semiconductor chip 3 and covers the lower side of the latter. The encapsulation material 40 is subsequently solidified, for example thermally.

In the optional method step S4, the filling 5 is produced, see also FIG. 11.

FIGS. 25 to 33 illustrate a further exemplary embodiment of the housing 2. The housing 2 comprises the drainage structures 24, which are for example cross-shaped in a plan view and which are respectively formed by the strips 26. Furthermore, as in all other exemplary embodiments as well, the housing 2 may have a positioning mark 82. The positioning mark 82 is located for example at an upper corner of the housing 2, so that its orientation is clearly visible during mounting of the housing 2.

Unlike the housing 2 of FIG. 1, the housing of FIG. 25 comprises a thermal conductor structure 29 in addition to the two electrical conductor structures 23. The thermal conductor structure 29 is integrated in the same lead frame 8 as the electrical conductor structures 23, see also FIG. 26. For example, the thermal conductor structure 29 is arranged centrally between the electrical conductor structures 23. Two of the strips 26 which extend transversely with respect to the longitudinal axis may end on the thermal conductor structure 29.

The lead frame 8 is for example half-etched, see FIG. 8. This means that an outwardly visible surface of the lead frame 8 may be shaped differently on the chip mounting side 22 than on a housing lower side 20, see also FIGS. 29 and 30, in which the housing base body 21 is shown for illustration as a transparent body. In this case, FIG. 29 represents a view of the housing lower side 20 and FIG. 30 represents a view of the chip mounting side 22. In FIG. 28, the housing base body 21 is again shown as opaque and the housing lower side 20 is represented. Such a half-etched lead frame 8 may also be used correspondingly in all other exemplary embodiments.

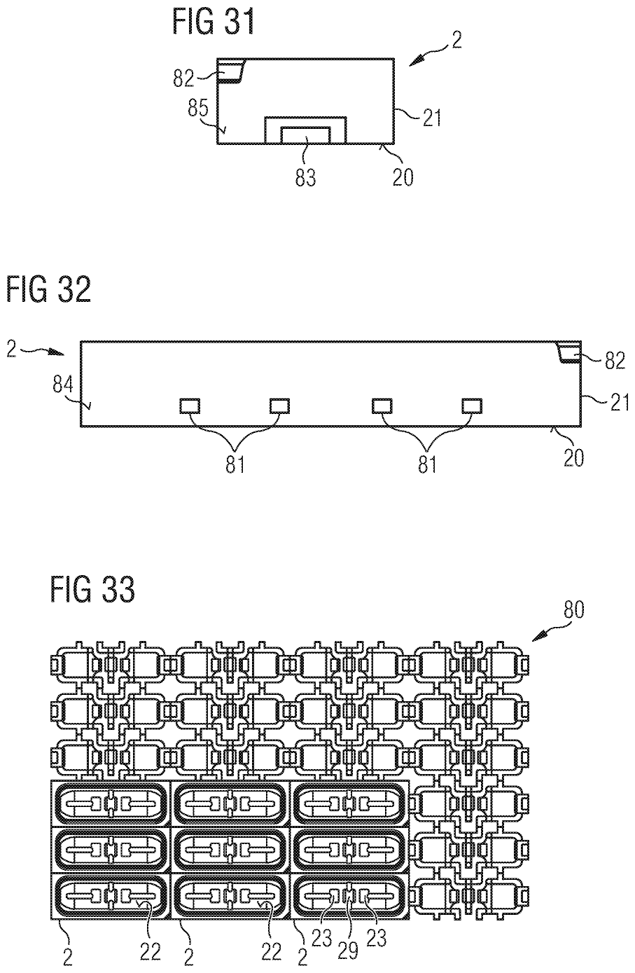

FIG. 31 illustrates a side view of a transverse side face 85 of the housing base body 21. The transverse side face 85 may be rectangular as seen in a plan view. Optionally, there is a solder control structure 83 on each of two mutually opposite transverse side faces 85. The solder control structures 83 are produced, in particular, by laterally exposed recesses in the lead frame 8 from the housing lower side 20. The solder control structures 83 are therefore formed integrally with the electrical conductor structures 23 and are located on lateral extensions of the electrical conductor structures 23. Conversely, according to FIG. 1 there are solder control structures pairwise on longitudinal side faces of the housing base body 21.

The lead frame 8 may have its maximum thickness in regions next to the solder control structures 83, as well as in the region of the electrical conductor structures 23 and of the thermal conductor structure 29. In all other regions, the lead frame 8 may be thinner because of the half-etching. Preferably, on the housing lower side 20 the lead frame 8 reaches side edges of the housing lower side 20 only in the region of the solder control structures 83 on the transverse side faces 85.

It is possible for the thermal conductor structure 29 to be narrower along the longitudinal axis on the housing lower side 20 than on the chip mounting side 22.

The lead frame design, as depicted particularly in FIG. 26, may also be regarded as a mesh design. In this case, the electrical contact pads 23, 25 for the semiconductor chip 3 are connected to the respective solder control structures 83 on the transverse side faces 85. This design may minimize thermomechanical stresses which act on a chip solder connection.

This design may furthermore achieve the effect that the lead frame 8 is substantially concealed under a material of the housing base body 21, so that possible corrosion damage to the lead frame 8 does not cause any optical modification of the illumination characteristic of the semiconductor component 1. Furthermore, this design makes the lead frame structure so flexible at the panel level that a housing density may be higher than for conventional QFN designs.

This design of the lead frame 8 furthermore reduces the mechanical, chemical and optical interactions of the materials used in the housing 2 with one another. The development of new components and the material tests are therefore simplified and accelerated.

It may be seen in FIG. 32 that connecting bars 81 of the lead frame 8, cut through on a longitudinal side face 84 of the housing base body 21, are exposed. By means of these connecting bars 81, neighboring lead frames 8 are mechanically connected to one another in a lead frame panel 80, see also FIG. 27. This means that in the lead frame panel 80, the conductor structures 23, 29 are still short-circuited and integrally connected to one another. The connecting bars 81 are preferably distanced from the housing lower side 20, although they may lie in a common plane with the electrical contact pads 25 on the chip mounting side 22.

During the production of the housing 2, the lead frame panel 80 is preferably provided first and then the housing base bodies 21 are formed as a continuous body, compare also FIG. 33. Subsequently, individualization is carried out to form the individual housings 2, the connecting bars 81 being cut through.

Such a lead frame 8, as explained in detail particularly in connection with FIG. 26, may be employed in all other exemplary embodiments of the housing 2.

In other regards, the comments relating to FIGS. 1 to 24 apply accordingly for FIGS. 25 to 33.

FIG. 34 shows a further exemplary embodiment of the housing 2. In this case, the strips 26 are again arranged, for example, in the shape of a cross. Unlike in FIG. 1, the strips 26 which extend along the longitudinal axis A end at a distance from the side walls 28 and therefore still inside the cavity 28. In particular, these drainage structures 24 end while still inside the plane chip mounting side 22 and before the, for example rounded, cavity ends 48.

Such shorter limbs of the cross of the drainage structures 24, 26 along the longitudinal axis A may have the effect that the, for example jetted, encapsulation material 40 for the encapsulation 4, for example a TiO₂ silicone, may then be jetted onto a plane region, in particular of the chip mounting side 22 and only subsequently come in contact with the drainage structures 24, 26. This means that the land zones 44 may lie along the longitudinal axis A between the shortened drainage structures 24, 26 and the associated cavity ends 48 or the associated side walls 48. This leads to more uniform underpinning of the semiconductor chip 3 with the encapsulation material 40.

Such shortened drainage structures 24, 26 may also be used in all other exemplary embodiments.

In other regards, the comments relating to FIGS. 25 to 33 apply accordingly for FIG. 34.

In the exemplary embodiment of FIG. 35, it is shown that the thermal conductor structure 29 may also be narrower along the longitudinal axis A than the electrical contact pieces 23. In this case, all the conductor structures 23, 29 may have the same extent in a direction perpendicular to the longitudinal axis A and terminate flush with one another. The same is also possible in all other exemplary embodiments.

In other regards, the comments relating to FIGS. 25 to 34 apply accordingly for FIG. 35.

Conversely, the thermal conductor structure 29 may also be widened and, for example, exceed an extent of the electrical conductor structures 23 along the longitudinal axis A, for example by at least a factor of 1.5 or at least a factor of 2 and/or by at most a factor of 5 or at most a factor of 3. This applies in particular if the electrical conductor structures 23 are adapted for application of bonding wires for electrical connection of the at least one optoelectronic semiconductor chip 3. The same is also possible in all other exemplary embodiments.

In other regards, the comments relating to FIGS. 25 to 35 apply accordingly for FIG. 36.

The component parts shown in the figures preferably follow one another in the order specified, in particular follow one another directly, in the order specified, unless otherwise described.

Component parts which do not touch in the figures preferably have a distance from one another. If lines are shown as being parallel to one another, the assigned faces are preferably likewise aligned parallel to one another. Furthermore, the relative positions of the component parts shown with respect to one another are reproduced correctly in the figures, unless otherwise described.

The invention as described here is not restricted by the description with the aid of the exemplary embodiments. Rather, the invention includes any new feature and any combination of features, which in particular involves any combination of features in the patent claims, even if this feature or this combination is not itself explicitly indicated in the patent claims or exemplary embodiments.

This patent application claims the priority of the German Patent Applications 10 2020 100 542.3 and 10 2020 106 250.8, the disclosure content of which is incorporated here by reference.

### LIST OF REFERENCES

1 optoelectronic semiconductor component
2 housing
20 housing lower side
21 housing base body
22 chip mounting side of the housing base body
23 electrical conductor structure
24 drainage structure
25 electrical contact pad
26 strip of the drainage structure
27 cavity (reflector trough)
28 side wall of the cavity
29 thermal conductor structure
3 optoelectronic semiconductor chip
30 sapphire substrate
31 electrical connection face
32 lower side of the semiconductor chip
33 emission side of the semiconductor chip
34 side face of the semiconductor chip
35 semiconductor layer sequence
36 active zone
37 mirror
38 region of the lower side not covered by the mirror
4 reflective encapsulation
40 encapsulation material
41 channel
42 matrix material
43 reflective particle
44 land zone for the encapsulation material
47 further edge
48 rounded cavity end
49 edge
5 filling
6 connecting means
7 mold
71 channel for the drainage structure
72 trough for the cavity
8 lead frame
80 lead frame panel
81 connecting bar
82 positioning mark
83 solder control structure
84 longitudinal side face of the housing base body
85 transverse side face of the housing base body
A longitudinal axis
S method step

1. A housing for an optoelectronic semiconductor component, having
a housing base body, which has a chip mounting side,
at least two conductor structures in and/or on the housing base body, and
a plurality of drainage structures on the chip mounting side,
wherein
the electrical conductor structures on the chip mounting side form electrical contact pads for at least one optoelectronic semiconductor chip, and
the drainage structures are configured as feeds for a liquid encapsulation material to the electrical contact pads,
the drainage structures are respectively configured integrally with the housing base body, and
the drainage structures respectively comprise a strip and the strips each rise above other parts of the chip mounting side.

2. The housing as claimed in claim 1, furthermore comprising at least one thermal conductor structure,
wherein the at least one thermal conductor structure and the electrical conductor structures are respectively formed by metal lead frame parts,
wherein the lead frame parts are mechanically connected to one another by the housing base body.

3. The housing as claimed in claim 1, wherein the drainage structures are respectively formed by at least one edge on the strips.

4. The housing as claimed in claim 1,
wherein the drainage structures are respectively formed by at least two of the strips and these strips define a channel, and the strips extend parallel to one another with a tolerance of at most 10° inside the relevant drainage structure.

5. The housing as claimed in claim 1,
wherein a cross section of the strips is rectangular or trapezoidal or dome-shaped, or a mixture thereof.

6. The housing as claimed in claim 1,
wherein the housing base body comprises a cavity which forms a reflector trough,
wherein the reflector trough is formed all around by side walls of the housing base body and the side walls enclose the chip mounting side.

7. The housing as claimed in claim 6,
wherein the side walls merge continuously into the chip mounting side so that the side walls and the chip mounting side form a rounding locally or all around with a radius of curvature of at least 1 mm as seen in a cross section perpendicular to the electrical contact pads.

8. The housing as claimed in claim 1,
which is rectangular or approximately rectangular in a plan view of the chip mounting side,
wherein two of the drainage structures extend along a longitudinal axis of the housing base body and two further, in particular shorter, drainage structures are oriented transversely with respect to the longitudinal axis, as seen in a plan view of the chip mounting side.

9. The housing as claimed in claim 8,
wherein the drainage structures which are oriented transversely with respect to the longitudinal axis (A) are adapted to guide the liquid encapsulation material from longer side walls of the cavity to an intermediate space between the electrical contact pads.

10. The housing as claimed claim 9,
wherein at least one of the drainage structures which extend along the longitudinal axis (A) of the housing base body ends at a distance from the side walls.

11. An optoelectronic semiconductor component, having
a housing as claimed in claim 1,
at least one optoelectronic semiconductor chip on the electrical contact pads, and
a reflective encapsulation, which is produced from the liquid encapsulation material,
wherein
the encapsulation reaches under the at least one optoelectronic semiconductor chip and leaves side faces of the at least one semiconductor chip predominantly or entirely free.

12. The optoelectronic semiconductor component as claimed in claim 11,
wherein the at least one optoelectronic semiconductor chip bears on all or on at least three of the drainage structures.

13. The optoelectronic semiconductor component as claimed in claim 11,
wherein a lower side, facing toward the chip mounting side, of the at least one optoelectronic semiconductor chip is entirely covered by the reflective encapsulation together with a connecting means and together with the drainage structures,
wherein the connecting means is a solder or comprises a solder, and/or wherein the connecting means is covered all around entirely or predominantly by the encapsulation in a direction parallel to the chip mounting side.

14. The optoelectronic semiconductor component as claimed in claim 11,
wherein the encapsulation is composed of a matrix material and of reflective particles and is white,
wherein the drainage structures preferably have a height of at least 10 μm or 30 μm or 60 μm and/or at most 200 μm or 100 μm or 80 μm, in particular between 30 μm and 100 μm inclusive, above the chip mounting side,
wherein the at least one optoelectronic semiconductor chip is a sapphire flip-chip, so that all the electrical connection faces of the semiconductor chip are uniquely assigned to the electrical contact pads,
wherein a sapphire substrate of the semiconductor chip faces away from the chip mounting side.

15. The optoelectronic semiconductor component as claimed in claim 11,
comprising at least one thermal conductor structure, wherein the at least one thermal conductor structure and the electrical conductor structures are respectively formed by metal lead frame parts,
wherein the lead frame parts are mechanically connected to one another by the housing base body,
wherein the at least one optoelectronic semiconductor chip is applied both on the electrical conductor structures and on the at least one thermal conductor structure, and wherein the thermal conductor structure is electrically separated from the electrical conductor structures and is free of an electrical function.

16. The optoelectronic semiconductor component as claimed in claim 11,
wherein the at least one optoelectronic semiconductor chip comprises a mirror on a lower side facing toward the chip mounting side,
wherein the mirror ends at a distance from an edge of the lower side and a region, not covered by the mirror, of the lower side is covered entirely or predominantly by the encapsulation.

17. The optoelectronic semiconductor component as claimed in claim 11, furthermore comprising a filling which covers the at least one optoelectronic semiconductor chip and touches the encapsulation and encloses it all around in a plan view of the chip mounting side,
wherein the filling preferably contains one or more phosphors, so that the semiconductor chip generates in particular blue light and the semiconductor component is preferably adapted for the emission of white light.

18. Method for producing an optoelectronic semiconductor component as claimed in claim 11, having the following steps in the order specified:
A) producing the housing,
B) mounting the at least one optoelectronic semiconductor chip on the electrical contact pads, and
C) producing the encapsulation,
wherein
an encapsulation material, on which the encapsulation is produced, is applied in the liquid state in land zones,
the land zones lie next to the optoelectronic semiconductor chip as seen in a plan view,
the drainage structures extend through the land zones or begin in the land zones, and
the encapsulation material passes from the land zones through the drainage structures to the optoelectronic semiconductor chip, in particular by capillary action.

19. The method as claimed in claim 18,
wherein the housing is produced in step A) by means of casting, injection molding and/or pressing, so that the drainage structures are produced integrally with the housing base body and from the same material without connecting means.

20. The method as claimed in claim 18,
wherein the encapsulation material is applied exclusively in the region of the land zones in step C) by means of jetting.
